(19) United States
(12) Patent Application Publication
(10) Pub. No.: US 2022/0336713 A1
(43) Pub. Date: Oct. 20, 2022

(54) OPTOELECTRONIC SEMICONDUCTOR CHIP AND METHOD FOR PRODUCING THEREOF

(71) Applicant: OSRAM Opto Semiconductors GmbH, Regensburg (DE)

(72) Inventor: Ivar TANGRING, Regensburg (DE)

(21) Appl. No.: 17/636,037

(22) PCT Filed: Aug. 7, 2020
(86) PCT No.: PCT/EP2020/072316

§ 371 Date: Feb. 17, 2022

(30) Foreign Application Priority Data
Aug. 21, 2019 (DE) 10 2019 122 460.8

(51) Int. Cl. H01L 33/44; H01L 33/00

(52) U.S. Cl. CPC H01L 33/44; H01L 33/0075; H01L 33/0093; H01L 33/32

(57) ABSTRACT

An optoelectronic semiconductor chip may include a semiconductor body having an upper side and flanks running transversely to the upper side which delimit the semiconductor body in a lateral direction. The flanks are each covered with a first passivation layer. In the region of the flanks in each case a second passivation layer may be arranged between the first passivation layer and the semiconductor body, the index of refraction of the second passivation layer being lower than the index of refraction of the first passivation layer. The indices of refraction may be understood to be the indices of refraction for the radiation generated by the active layer during operation.

### CROSS-REFERENCE TO RELATED APPLICATIONS

The present application is a national stage entry according to 35 U.S.C. § 371 of PCT application No.: PCT/EP2020/072316 filed on August 7, 2020; which claims priority to German Patent Application Ser. No.: 10 2019 122 460.8 filed on Aug. 21, 2019; all of which are incorporated herein by reference in their entirety and for all purposes.

### TECHNICAL FIELD

An optoelectronic semiconductor chip is provided. Further, a method for producing an optoelectronic semiconductor chip is provided.

### BACKGROUND

A problem to be solved is, inter alia, to specify an optoelectronic semiconductor chip which is distinguished by a particularly high efficiency. A further problem to be solved is, inter alia, to specify a method for producing such an optoelectronic semiconductor chip.

### SUMMARY

According to at least one embodiment of the optoelectronic semiconductor chip, said semiconductor chip comprises a semiconductor body having an active layer and a top side. The semiconductor body is based, for example, on a III-V compound semiconductor material. The semiconductor material is, for example, a nitride compound semiconductor material, such as AlₙIn₁₋ₙ₋ₘGaₘN, or a phosphide compound semiconductor material, such as AlₙIn₁₋ₙ₋ₘGaₘP, or an arsenide compound semiconductor material, such as AlₙIn₁₋ₙ₋ₘGaₘAs or AlₙIn₁₋ₙ₋ₘGaₘAsP, where 0≤n≤1, 0≤m≤1 and m+n≤1. However, the semiconductor body can have dopants and additionally constituents. For the sake of simplicity, however, only the essential constituents of the crystal lattice of the semiconductor body, that is, Al, As, Ga, In, N or P, are indicated, even if they can be partially replaced and/or supplemented by small amounts of further substances. The semiconductor body may be based on GaN.

The semiconductor body comprises an active layer which generates electromagnetic radiation during operation. The active layer contains, in particular, at least one quantum well structure in the form of a single quantum well, SQW for short, or in the form of a multi-quantum well structure, MQW for short. The semiconductor body may include one, in particular exactly one, contiguous active layer.

For example, the semiconductor body comprises two doped regions, a first doped region and a second doped region, wherein the active layer is arranged between the first doped region and the second doped region. For example, the first doped region is arranged on a side of the active layer facing the top side. In this case, the second doped region is arranged on a side of the active layer facing away from the top side. The first doped region, the second doped region and/or the active layer may be formed in a continuous manner, in particular in a simple continuous manner.

For example, the semiconductor body comprises a p-doped region, which is in particular the second doped region, and an n-doped region, which is in particular the first doped region, wherein the active layer is arranged between the p-doped region and the n-doped region. In particular, in the intended operation, the active layer generates electromagnetic radiation, for example, in the green or red spectral range or in the UV range or in the IR range. In embodiments, radiation is generated in the blue spectral range. For example, a majority of the electromagnetic radiation generated by the active layer in the semiconductor body is emitted at the top side. In particular, more than 60% or more than 70%, such as more than 80%, of the generated electromagnetic radiation is emitted via the top side.

According to at least one embodiment, the semiconductor body comprises flanks which run transversely to the top side and delimit the semiconductor body in a lateral direction. In this case and in the following, a lateral direction is understood to mean a direction which runs parallel to the top side of the semiconductor body. For example, the flanks run perpendicular to the top side of the semiconductor body. In particular, the flanks form side surfaces of the semiconductor body.

A semiconductor chip is understood here and hereinafter as a separately manageable and electrically contactable element. A semiconductor chip may include exactly one originally contiguous region of the semiconductor body grown in the wafer composite. The semiconductor body of the semiconductor chip may be designed to be continuous. The lateral extent of the semiconductor chip is, for example, at most 5% or at most 10% greater than the lateral extent of the semiconductor body.

For example, a lateral extent of the semiconductor body is at most 10% or at most 5% or at most 1% greater than a lateral extent of the active layer. In particular, a lateral extent of the first and/or second doped region and the lateral extent of the active layer differ from one another by at most 10% or at most 5% or at most 1%. In other words, the first doped region, the second doped region, the active layer and the semiconductor body have substantially the same lateral extent. The lateral extent of the semiconductor chip, of the semiconductor body, of the first doped region, of the second doped region or of the active layer is, in particular, in each case an average lateral extent.

For example, the optoelectronic semiconductor chip can be used in a headlight, in particular a headlight for automobiles, or as a flash light.

According to at least one embodiment, the flanks are each covered with a first passivation layer. In particular, the flanks of the semiconductor body are completely covered with the first passivation layer. For example, the first passivation layer is a dielectric layer. In particular, the first passivation layer is electrically insulating. In embodiments, the first passivation layer comprises silicon nitride, Si₃N₄, or consists thereof. For example, the first passivation layer is transparent to the electromagnetic radiation generated by the active layer.

According to at least one embodiment, a second passivation layer is arranged in each case between the first passivation layer and the semiconductor body in the region of the flanks. For example, the second passivation layer is in direct contact with the semiconductor body. The second passivation layer may cover the flank in the region of the active layer of the semiconductor body. For example, the first and second passivation layers are in direct contact. In particular, the second passivation layer is a dielectric layer. The second passivation layer may be transparent to the electromagnetic radiation generated by the active layer. For example, the second passivation layer comprises silicon dioxide, SiO₂ for short, and/or magnesium fluoride, MgF₂ for short.

According to at least one embodiment, the refractive index of the second passivation layer is smaller than the refractive index of the first passivation layer. The refractive indices mean the refractive indices for the radiation generated by the active layer during operation. In particular, the refractive indices each relate to the dominant wavelength of the radiation generated in the active layer. The dominant wavelength is the wavelength at which the emission spectrum of the semiconductor body has a global intensity maximum. For example, the refractive index of the second passivation layer is at most 80%, such as at most 70%, of the refractive index of the first passivation layer. For example, the refractive index of the first passivation layer is 2.0, if it comprises silicon nitride. The refractive index of the second passivation layer is, for example, 1.46 or 1.39, if it comprises silicon dioxide or magnesium fluoride. The refractive index is understood here in particular to mean the real part of the complex refractive index. Furthermore, the refractive index of a layer is the refractive index averaged over said layer.

In at least one embodiment, the optoelectronic semiconductor chip comprises a semiconductor body having an active layer, a top side and flanks extending transversely to the top side, which delimit the semiconductor body in a lateral direction. The flanks are each covered with a first passivation layer. A second passivation layer is arranged in each case between the first passivation layer and the semiconductor body in the region of the flanks, wherein the refractive index for the radiation of the second passivation layer generated by the active layer during operation is smaller than the refractive index of the first passivation layer.

An optoelectronic semiconductor chip described here is based, inter alia, on the following considerations. In order to achieve a high efficiency of the semiconductor chip, it is necessary to keep the absorption of radiation at the flanks as low as possible. For this purpose, material from which the first passivation layer is formed could be removed, reduced or offset from the optical path at the flanks. This material can have a high refractive index and therefore cause little total reflection of radiation at the flanks. Thus, much radiation which is emitted via the side surfaces of the semiconductor body reaches further layers which are arranged downstream in the emission direction and which can be highly absorbent. In addition, the first passivation layer may cause direct losses of radiation, for example, due to absorption.

The optoelectronic semiconductor chip described here makes use, inter alia, of the idea of arranging a second passivation layer in the region of the flanks between the first passivation layer and the semiconductor body. The second passivation layer has a lower refractive index than the first passivation layer. Due to the lower refractive index of the second passivation layer, total internal reflection occurs in the region of the flanks. Radiation losses can thus be reduced. The second passivation layer may be transparent, since at least part of the reflected radiation penetrates into the material even in the case of total reflection.

Advantageously, the efficiency of the optoelectronic semiconductor chip can be improved by lower radiation losses in the region of the flanks. For example, the absorption of radiation at the edges can be reduced from 5% to 2% and the efficiency of the semiconductor chip can be increased by up to 3%.

According to at least one embodiment of the optoelectronic semiconductor chip, the second passivation layer completely covers the flanks. Advantageously, radiation losses at the flanks can be reduced particularly well by complete coverage of the flanks with the second passivation layer.

According to at least one embodiment, the second passivation layer covers the flanks in each case by at least 60% and by at most 80%. In particular, the second passivation layer covers the flanks in each case by at most 90% or by at most 95%. For example, the second passivation layer completely covers flanks of the second doped region and the active layer. In particular, flanks of the first doped region are by at least 20% or by at least 50% or by at least 70% or completely covered by the second passivation layer. For example, the second passivation layer is formed continuously, in particular continuously in a simple manner, on the flanks, as a result of which the flank is divided into two simply contiguous regions. The regions differ in this case due to the covering with the second passivation layer. In embodiments, the region of the flank which is free of the second passivation layer adjoins the top side of the semiconductor body. The second passivation layer can thus advantageously be protected from environmental influences and/or during processing of the semiconductor body from the direction of the top side.

According to at least one embodiment, a high-refractive dielectric layer having a greater refractive index than the second passivation layer is arranged between the first passivation layer and the second passivation layer. In particular, the high-refractive dielectric layer has a refractive index which is at least 1.2 times or at least 1.5 times or at least 2 times as large as the refractive index of the second passivation layer. In addition, the high-refractive dielectric layer may have a refractive index greater than, for example, at least 1.1 times as large or at least 1.5 times as large as the refractive index of the first passivation layer. For example, the high-refractive dielectric layer comprises titanium dioxide or is formed therefrom. In embodiments, the high-refractive dielectric layer is in direct contact with the second passivation layer. The high-refractive dielectric layer may have a thickness, measured perpendicular to the flank, which, within the scope of the production tolerance, corresponds to a quarter of the dominant wavelength of the radiation generated by the active layer. Furthermore, a low-refractive dielectric layer, which directly adjoins the high-refractive dielectric layer and has a lower refractive index than the high-refractive dielectric layer, is arranged between the high-refractive dielectric layer and the first passivation layer. For example, the refractive index of the high-refractive dielectric layer is at least 1.2 times or at least 1.5 times or at least 2 times as large as that of the low-refractive dielectric layer. The low-refractive dielectric layer is formed, for example, from silicon dioxide. Advantageously, due to interference effects, the reflectivity in the region of the flanks can be increased with such a highly-refractive layer, in particular in interaction with the low-refractive layer.

According to at least one embodiment, the second passivation layer has a thickness of at least 100 nm. The thickness is measured perpendicular to the flank. In particular, the thickness of the second passivation layer is greater than half the dominant wavelength of the radiation generated by the active layer. For example, the average thickness of the second passivation layer on the flank is at least 100 nm or at least 250 nm. Alternatively or additionally, the thickness of the second passivation layer is at most 1000 nm or at most 800 nm or at most 600 nm.

The thickness may vary along one or more directions parallel to the flank. In particular, the thickness of the second passivation layer at each point of the flank is then at least 100 nm or at least 250 nm. Advantageously, such a thick second passivation layer can prevent or avoid an evanescent wave, which forms in the second passivation layer, being transmitted through the second passivation layer. An evanescent wave is to be understood to mean an electromagnetic field which forms within the second passivation layer when total reflection occurs at the second passivation layer. The amplitude of this field, starting from the side of the second passivation layer at the total reflection, decays exponentially.

According to at least one embodiment, a metal layer is arranged on a side of the first passivation layer facing away from the semiconductor body. For example, the metal layer comprises titanium, platinum, nickel, copper or is formed from one of these materials or from a mixture of these materials. For example, the metal layer is configured to energize the optoelectronic semiconductor chip in the intended operation. In particular, the doped region of the semiconductor body, which is arranged between the top side and the active layer, is supplied with current via the second metal layer.

According to at least one embodiment, the top side of the semiconductor body has coupling-out structures. For example, the coupling-out structures have a triangular cross-section, wherein the sectional plane runs perpendicular to the top side. In particular, the coupling-out structures are designed in the form of pyramids or cones. Advantageously, more radiation can be coupled out via the top side of the semiconductor body by coupling-out structures, since less radiation is reflected back into the semiconductor body by total reflection.

According to at least one embodiment, the metal layer has a thickness of at least 500 nm measured perpendicular to the flank. The first passivation layer may include two sections. The first section runs parallel to the flank and the second section runs transversely to the flank. The course of a section of a layer is understood to mean the course of the main extension plane of the respective section. The second portion extends away from the semiconductor body. The metal layer adjoins the second and may also adjoin the first portion of the first passivation layer. Advantageously, the second section of the first passivation layer protects the metal layer against environmental influences and/or during the further processing of the semiconductor chip.

According to at least one embodiment, the semiconductor body is based on AlₙIn₁₋ₙ₋ₘGaₘN. The first passivation layer comprises silicon nitride and the second passivation layer comprises silicon dioxide. For example, the semiconductor body has a refractive index of 2.4. In particular, the first passivation layer is formed from silicon nitride, and the second passivation layer is formed from silicon dioxide.

Further, a method for producing an optoelectronic semiconductor chip is provided. The optoelectronic semiconductor chip described here can be produced in particular by such a method. This means that all the features disclosed for the optoelectronic semiconductor chip are also disclosed for the method and vice versa.

According to at least one embodiment, the method comprises a step A) in which a semiconductor body having an active layer, a top side and a lower side opposite the top side is provided on a growth substrate. The active layer is configured to generate electromagnetic radiation. In this case, the top side of the semiconductor body faces the growth substrate.

For example, the growth substrate comprises sapphire or is formed from sapphire. In particular, the semiconductor body is epitaxially deposited on the growth substrate, for example, by means of metal-organic gas phase epitaxy, MOVPE for short, or metal-organic chemical vapor deposition, MOCVD for short. The semiconductor body is grown, for example, with a thickness of at least 2 μm measured perpendicular to its main extension plane. The thickness may be between 4 μm and 6 μm inclusive.

According to at least one embodiment, in a method step B), the method comprises etching mesa trenches into the semiconductor body, starting from the lower side of the semiconductor body. The mesa trenches have, for example, in each case a width, measured parallel to the lower side of the semiconductor body, between 500 nm and 1500 nm inclusive.

A directed etching process may be used, such as ion or plasma etching, for example. For example, during the etching process, the region of the semiconductor body which is not etched is protected with a mask.

According to at least one embodiment, a second passivation layer is applied to flanks and bottom surfaces of the mesa trenches in a step C). In this case, the flanks delimit the mesa trenches in a lateral direction and the bottom surfaces delimit the mesa trenches in a vertical direction, perpendicular to the lateral direction. For example, the flanks extend transversely to the lower side of the semiconductor body and the bottom surface runs parallel or substantially parallel thereto. The flanks of the mesa trenches are formed by the semiconductor body.

For example, prior to the application of the second passivation layer, a mask such as may be used in step B) is removed. In this case, the second passivation layer is in particular likewise applied to the lower side of the semiconductor body. Alternatively or additionally, the lower side of the semiconductor body is masked before the application of the second passivation layer. For example, the same mask as in step B) can be used for this purpose or a further mask different from the mask used in step B) is used.

The second passivation layer may be applied in such a way that it has a thickness at the flanks, measured perpendicular to the flank, of at least 250 nm. For example, the second passivation layer is applied by means of sputtering or chemical vapor deposition, CVD for short.

According to at least one embodiment of the method, the second passivation layer is removed in a step D) in the region of the bottom surfaces, wherein the flanks in each case remain covered with the second passivation layer. For example, the second passivation layer is removed by etching. In particular, in the case where it is attached to the lower side of the semiconductor body, the second passivation layer is also removed there. In particular, the top side and the lower side of the semiconductor body are free of the second passivation layer after process step D). In embodiments, when the second passivation layer is removed from the bottom surface, the thickness of the second passivation layer in the region of the flanks is not reduced or reduced by at most 10%. In embodiments, the second passivation layer has a thickness of at least 100 nm on the flank after step D).

According to at least one embodiment, the method comprises a method step E) in which a first passivation layer is applied to flanks and bottom surfaces of the mesa trenches. The refractive index of the second passivation layer is smaller than the refractive index of the first passivation layer, wherein the refractive indices each relate to the radiation generated by the active layer. In embodiments, the first passivation layer is applied directly to the second passivation layer. For example, the first passivation layer is likewise applied to the lower side of the semiconductor body. Alternatively, the lower side of the semiconductor body can be masked, so that, after a suitable mask has been removed, the lower side of the semiconductor body is free of the first passivation layer.

The methods described here are based, inter alia, on the following considerations. In certain applications, it may be necessary that, prior to removing the growth substrate, mesa trenches are etched into a semiconductor body, for example, when the semiconductor body is mounted on a plastic carrier that does not withstand thermal stresses during etching. In this case, it may be necessary to coat the bottom surfaces of the mesa trenches with a dielectric first passivation layer in order to enable detachment of the growth substrate also in these regions. The detachment can be carried out using a laser, also referred to as a laser lift-off, abbreviated LLO. The flanks of the mesa trenches can also be coated with the first passivation layer. As a result, radiation losses at the flanks of the semiconductor body can occur due to transmission and absorption. For example, the difference between the refractive indices of the first passivation layer and the semiconductor body is so low that little total reflection occurs at the first passivation layer.

The advantage of the method described here is, inter alia, that a second passivation layer can be arranged on the flanks between the first passivation layer and the semiconductor body, while in the region of the bottom surfaces the first passivation layer is in direct contact with the growth substrate. Since the refractive index of the second passivation layer is less than the refractive index of the first passivation layer, total reflection occurs on the flanks, as a result of which radiation losses for laterally emitted radiation can be reduced. At the same time, due to the first passivation layer, the growth substrate can be detached in the region of the bottom surfaces and in the region of the semiconductor body in a single, common method step.

According to at least one embodiment of the method, in method step B) the semiconductor body is etched in the region of the mesa trenches to such an extent that in these regions after the etching the semiconductor body has a thickness of at least 10% and at most 40% of the average thickness of the non-etched semiconductor body. In this case, the thickness is measured perpendicular to the lower side of the semiconductor body. For example, the average thickness of the non-etched semiconductor body is between 4 μm and 6 μm, in particular about 5 μm. In particular, in this case, the average thickness of the semiconductor body in regions of the mesa trenches is between 1 μm and 2 μm inclusive. The mesa trenches thus each have a depth measured perpendicular to the lower side, for example, between 3 μm and 4 μm inclusive.

According to at least one embodiment, in method step B) the semiconductor body is completely etched away in the region of the mesa trenches. For example, the mesa trenches separate the semiconductor body into two or more sections which are connected to one another after the etching only via the growth substrate. In particular, the growth substrate is exposed in the region of the mesa trenches.

In particular, after the application of the second passivation layer in step C) and after the removal of the second passivation layer in step D), a part of the second passivation layer is in direct contact with the growth substrate. For example, a contact region in which the second passivation layer and the growth substrate are in contact have a width between 100 nm and 250 nm inclusive.

Advantageously, in such a broad contact region, the growth substrate can be removed by means of a laser even if the contact between the second passivation layer and the growth substrate is not dissolved in the contact region by the laser. A pressure which builds up during the detachment of the semiconductor body from the growth substrate by means of a laser can be sufficient to dissolve the contact between the second passivation layer and the growth substrate in the contact region.

Furthermore, after the removal of the growth substrate in this case, the second passivation layer is exposed on the top side of the semiconductor body. Thus, for example, in the case of an etching of coupling-out structures of the semiconductor body from the direction of its top side, a part of the second passivation layer is also removed.

According to at least one embodiment, in method step D), the semiconductor body is further completely removed in regions of the mesa trenches. For example, the semiconductor body is completely removed in the regions of the mesa trenches, in the event that this has not yet occurred in method step B). In particular, in method step D) the growth substrate is then exposed in the region of the mesa trenches.

According to at least one embodiment of the method, a directed etching process is used in method step D). For example, in method step D), the second passivation layer and/or the semiconductor body are removed by means of ion etching or plasma etching. In embodiments, the second passivation layer and/or the semiconductor body are etched only or predominantly in a direction perpendicular to the lower side. The flanks of the mesa trenches may not be attacked during etching. In particular, the thickness of the second passivation layer which is attached to the flanks remains substantially unchanged by the etching. In addition, such a directed etching method can also be used in method step B).

According to at least one embodiment, after method step C) and before method step D), a high-refractive dielectric layer is applied to the second passivation layer, which has a higher refractive index than the second passivation layer. In particular, the high-refractive dielectric layer has a refractive index which is at least 1.2 times or at least 1.5 times or at least 2 times as large as the refractive index of the second passivation layer. The high-refractive dielectric layer may be applied directly to the second passivation layer. For example, the high-refractive dielectric layer is applied using the same methods as the second passivation layer. In particular, the high-refractive dielectric layer is applied both in the region of the flanks and of the bottom surface.

A low-refractive dielectric layer may be applied to the high-refractive dielectric layer. In particular, the low-refractive dielectric layer is applied directly to the high-refractive dielectric layer. For example, the low-refractive dielectric layer is applied both in the region of the flanks and of the bottom surface. The low-refractive dielectric layer is formed, for example, from silicon dioxide and is applied by the same methods as the second passivation layer. Advantageously, the high-refractive dielectric layer is protected during further processing by the low-refractive dielectric layer.

According to at least one embodiment, in a further method step F) a metal layer is applied to a side of the first passivation layer facing away from the semiconductor body. In particular, the first metal layer is applied to the first passivation layer both in the region of the flanks and in the region of the bottom surfaces. For example, the metal layer is applied by sputtering. In particular, the metal layer is applied with a thickness of at most 500 nm, such as at most 200 nm, such as at most 50 nm. The metal layer comprises, for example, platinum, titanium, nickel or copper or is formed from one of these materials or is formed from a mixture of these materials. For example, in the intended operation, the semiconductor body is energized, inter alia, via the metal layer. In particular, during the further processing of the semiconductor chip, for example, from the direction of the top side, the metal layer can be protected by means of the first passivation layer.

According to at least one embodiment of the method, in a further method step G) a metal is galvanically deposited on the metal layer, so that the mesa trenches are filled by the metal. For example, copper is galvanically deposited. In embodiments, nickel is galvanically deposited. In particular, nickel has similar thermal properties to the semiconductor body, as a result of which the thermal stability of the optoelectronic semiconductor chip can be improved. Advantageously, the mechanical stability of the optoelectronic semiconductor chip can be increased by filled mesa trenches.

According to at least one embodiment of the method, in an additional method step H) the growth substrate is removed and the top side of the semiconductor body is provided with coupling-out structures. For example, the growth substrate is removed by means of a laser. The material of the first passivation layer, for example, silicon nitride, may have similar properties when detaching the growth substrate by means of lasers as the semiconductor body, which is based, for example, on AlₙIn₁₋ₙ₋ₘGaₘN. Advantageously, the growth substrate can thus be detached in a single process step both in the region of the semiconductor body and in the region of the mesa trenches by means of a laser.

For example, the lower side of the semiconductor body is provided with coupling-out structures by means of etching. KOH may be used as an etchant.

In embodiments, in a method step performed after step E), the semiconductor body is severed in the region of the mesa trenches in order to obtain individual semiconductor chips.

Method steps A) to H) may be carried out in alphabetical order. In particular, process steps A) to E) are carried out in alphabetical order.

### BRIEF DESCRIPTION OF THE DRAWINGS

Further advantages and advantageous embodiments and developments of the optoelectronic semiconductor chip result from the following exemplary embodiments illustrated in connection with schematic drawings. Identical, similar or identically acting elements are provided with the same reference signs in the figures. The figures and the size ratios of the elements shown in the figures are not to be considered to scale. Rather, individual elements can be shown in an exaggerated size for better illustration and/or for better understanding.

FIGS. 1 and 2 show views of various modifications of the optoelectronic semiconductor chip,

FIGS. 3, 4 and 6 show sectional views of various exemplary embodiments of the optoelectronic semiconductor chip,

FIGS. 5A to 5F show different positions in an exemplary embodiment of the method for producing an optoelectronic semiconductor chip.

### DETAILED DESCRIPTION

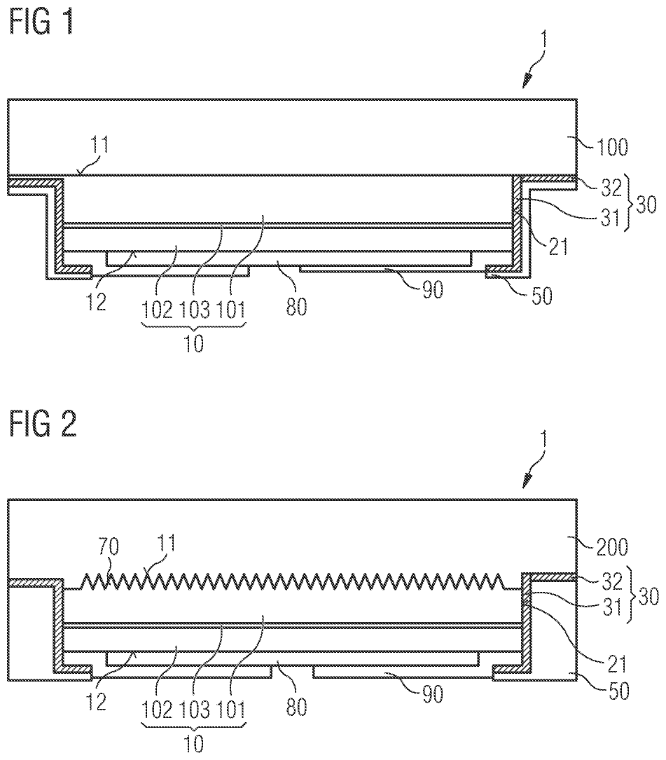

FIG. 1 shows a schematic sectional view of a first modification of an optoelectronic semiconductor chip 1. The semiconductor chip 1 comprises a growth substrate 100, on which a semiconductor body 10 is arranged. In the present case, the growth substrate 100 is formed from sapphire. A top side 11 of the semiconductor body 10 faces the growth substrate 100. The semiconductor body 10 has flanks 21 which extend transversely to the top side 11 and delimit the semiconductor body 10 in the lateral direction. The lower side 12 of the semiconductor body 10 lies opposite the top side 11. A first passivation layer 30 is arranged on the flanks 21 and has two sections 31, 32. The first section 31 runs parallel to the flanks 21, while the second section 32 runs parallel to the top side 11. The first section 31 is in direct contact with the flanks 21. The second section 32 is in direct contact with the growth substrate 100. The first passivation layer 30 is formed, for example, from silicon nitride.

A metal layer 50 is attached to the side of the first passivation layer 30 facing away from the semiconductor body 10. The metal layer 50 comprises, for example, nickel, platinum and/or titanium. A contact layer 80 is arranged on the lower side 12 of the semiconductor body 10. The contact layer 80 comprises, for example, one or more metals, such as gold, silver, copper and/or zinc.

The semiconductor body 10 has a first doped region 101, a second doped region 102 and an active layer 103, which is arranged between the doped regions 101, 102. The first doped region 101 is, for example, n-doped. The second doped region 102 is p-doped and is energized via the contact layer 80 during operation as intended. Alternatively, the doping of the doped regions 101, 102 is reversed. In order to electrically separate the contact layer 80 and the metal layer 50, the semiconductor chip 1 comprises an insulation layer 90. The insulation layer 90 is formed, for example, from a layer stack having a plurality of partial layers. The partial layers may each comprise silicon dioxide and/or silicon nitride.

FIG. 2 shows a schematic sectional view of a second modification of an optoelectronic semiconductor chip 1. In contrast to the modification of FIG. 1, the growth substrate 100 was removed, for example by means of laser lift-off. Furthermore, the top side 11 of the semiconductor body 10 has been provided with coupling-out structures 70, for example, by means of etching. KOH can be used as the etchant. During the detachment of the growth substrate 100 and the provision of the top side 11 with coupling-out structures 70, the metal layer 50 was protected in particular by the second section 32 of the first passivation layer 30.

Furthermore, in contrast to FIG. 1, a metal was galvanically deposited on the metal layer 50, for example, nickel. The thickness of the metal layer 50 was thus increased to, for example, at least 500 nm. The present modification comprises a conversion layer 200, which is configured to convert radiation emitted by the active layer 103 into radiation of a different wavelength, in particular a different wavelength range.

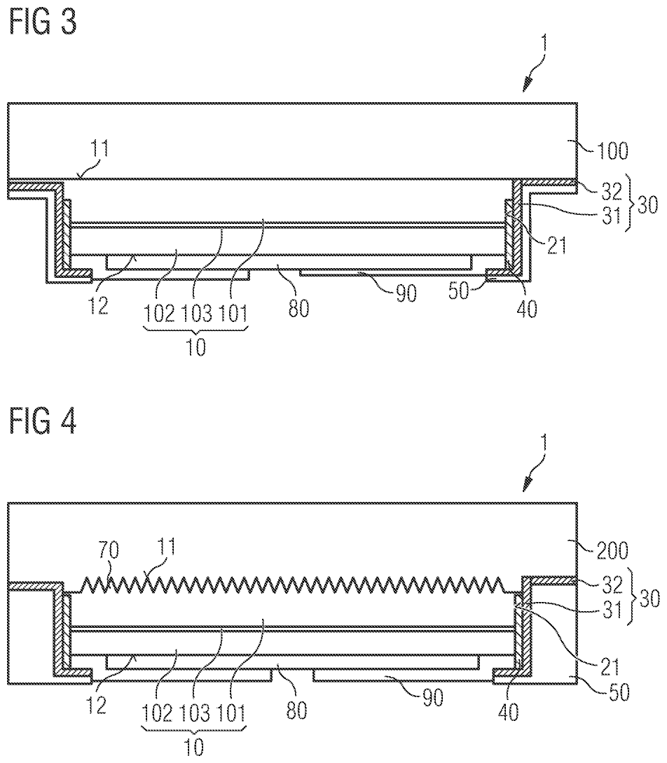

FIG. 3 shows a schematic sectional view of a first exemplary embodiment of an optoelectronic semiconductor chip 1. In contrast to the first modification of FIG. 1, the present optoelectronic semiconductor chip 1 comprises a second passivation layer 40 which is attached to the flanks 21. In particular, the second passivation layer 40 is arranged between the first passivation layer 30 and the semiconductor body 10 and is in direct contact with the semiconductor body 10. The second passivation layer 40 has a thickness perpendicular to the flank 21, which is between 250 nm and 1000 nm inclusive.

It can be seen in FIG. 3 that the second passivation layer 40 does not completely cover the flank 21, but, for example, at least 60% and at most 80% thereof. In particular, the first doped region 101 and the active layer 103 are completely covered by the second passivation layer in the region of the flank 21, while the second doped region 102 is covered, for example, by at least 20% and at most 90% of the second passivation layer 40 in the region of the flank 21. The first passivation layer 30 completely covers the flank 21. Thus, the region of the flanks 21, which in each case faces the top side 11, is free of the second passivation layer 40. In this region, the semiconductor body 10 covers the second passivation layer 40 in a lateral direction. Advantageously, in this region, the growth substrate 100 can be easily removed by means of laser lift-off, since the growth substrate 100 is not in direct contact with the second passivation layer 40. A further advantage results from the fact that the semiconductor body 10 in the region of the top side 11 protects the second passivation layer 40, for example, during the etching of the top side 11, in order to provide the latter with coupling-out structures 70.

The second passivation layer 40 has a refractive index which is smaller than the refractive index of the first passivation layer 30. The refractive indices relate in each case to the dominant wavelength of the radiation emitted by the active layer 103. The semiconductor body 10 may be based on AlₙIn₁₋ₙ₋ₘGaₘN and has a refractive index of 2.4, where 0≤n≤1, 0≤m≤1 and m+n≤1. The first passivation layer 30 may be formed from silicon nitride, which has a refractive index of 2.0 and the second passivation layer 40 is formed, for example, from silicon dioxide, which has a refractive index of 1.46. Thus, total reflection occurs for a greater proportion of the radiation which leaves the semiconductor body 10 in the region of the flanks 21 than is the case in the variations according to FIGS. 1 and 2. In addition, Fresnel reflection occurs at exit angles which do not satisfy the condition for total reflection.

The active layer 103, the first doped region 101 and the second doped region 102 each have substantially the same lateral extent as the semiconductor body 10. Furthermore, the active layer 103, the first and second doped regions 101, 102 are each formed in a simple continuous manner.

FIG. 4 shows a schematic sectional view of a second exemplary embodiment of an optoelectronic semiconductor chip 1 described here. FIG. 4 essentially shows the same features as

FIG. 3 with the difference that the growth substrate 100 has been removed, the metal layer 50 has a greater thickness and the top side 11 has been provided with coupling-out structures 70. Furthermore, a conversion layer 200 was applied to the top side of the semiconductor body 10.

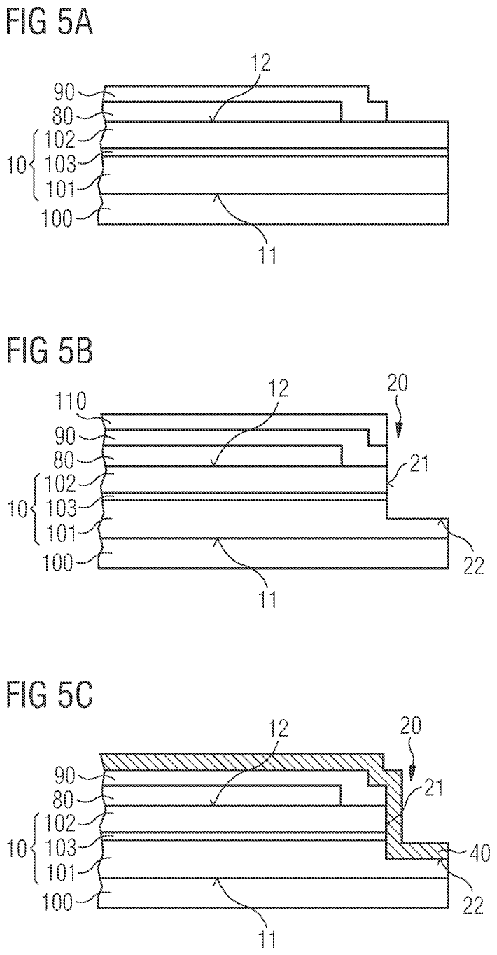

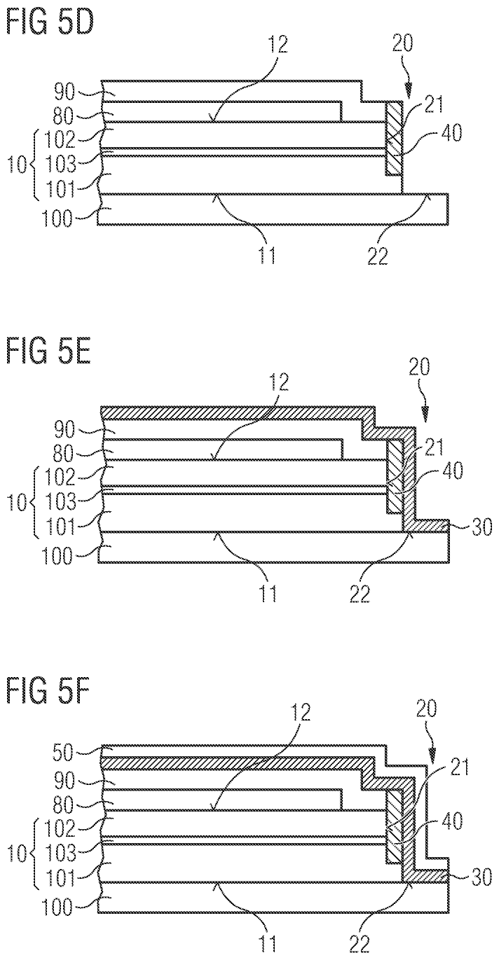

FIG. 5A shows a first situation in an exemplary embodiment of the method described here in a schematic sectional view. In method step A), a semiconductor body 10 having an active layer 103 configured to generate electromagnetic radiation, a top side 11 and a lower side 12 opposite the top side 11 is provided on a growth substrate 100. Only a section of the semiconductor body 10 is shown. The top side 11 faces the growth substrate 100. Furthermore, a contact layer 80 and an insulation layer 90 are attached to the lower side 12. The contact layer 80 comprises a metal.

FIG. 5B shows a second situation in an exemplary embodiment of the method described here. In a method step B), a mesa trench 20 was etched into the semiconductor body 10 starting from the lower side 12. The mesa trench 20 has a flank 21 which runs transversely, in particular perpendicularly, to the lower side 12 and a bottom surface 22 which runs substantially parallel to the lower side 12. The flank 21 and the bottom surface 22 delimit the mesa trench 20. The lower side 12 of the semiconductor body 10 and the contact layer 80 and the insulation layer 90 are covered with a mask 110 and thus protected during the etching process. For example, a directed etching process such as ion etching or plasma etching was used to etch the mesa trench 20.

In the present exemplary embodiment, the semiconductor body 10 has not been completely etched away in the region of the mesa trench 20. For example, the semiconductor body 10 has a thickness in the region of the mesa trench 20, measured perpendicular to its top side 11, between 1 μm to 2 μm inclusive, while the thickness of the semiconductor body 10 is between 4 μm and 6 μm inclusive.

In particular, the average thickness of the semiconductor body 10 in the region of the mesa trench 20 is at least as large as a maximum etching depth which is achieved in an optionally subsequent etching of coupling-out structures 70.

FIG. 5C shows a third situation in the process. In method step C), a second passivation layer 40 was applied to the flank 21 and the bottom surface 20 of the mesa trench 20. Furthermore, the second passivation layer 40 was applied to the side of the insulation layer 90 facing away from the lower side 12. For example, the second passivation layer 40 was applied by sputtering or CVD. The second passivation layer 40 has a thickness at the flanks 21, measured perpendicular to the flank 21, of at least 250 nm and at most 1000 nm.

FIG. 5D shows a fourth situation in the method in a schematic sectional view. In a method step D), the second passivation layer 40 was removed in the region of the bottom surface 22 and the lower side 12, so that the side of the insulation layer 90 facing away from the lower side 12 is free of the second passivation layer 40. The second passivation layer 40 only remains on the flank 21. In addition, the semiconductor body 10 has been completely removed in the region of the mesa trench 20, so that the growth substrate 100 has been exposed. For example, a directed etching process was used in step D).

As a result of the directed etching method, the semiconductor body 10 and the second passivation layer 40 have been etched only or predominantly in a direction perpendicular to the lower side 12, so that the thickness of the second passivation layer 40 remains substantially unchanged.

FIG. 5E shows a further situation in the process. In a method step E), a first passivation layer 30 was applied to the flank 21, the bottom surface 22 and the sides of the second passivation layer 40 and the insulation layer 90 facing away from the growth substrate 100. For example, the first passivation layer 30 was applied using the same methods as the second passivation layer 40. The first passivation layer 30 is based, for example, on silicon nitride and has a higher refractive index than the second passivation layer 40.

FIG. 5F shows a further situation in an exemplary embodiment of the method described here in a schematic sectional view. In a method step F), a metal layer 50 was applied to a side of the first passivation layer 30 facing away from the semiconductor body 10. For example, the metal layer 50 was applied by means of sputtering in order to achieve a low layer thickness of at most 200 nm.

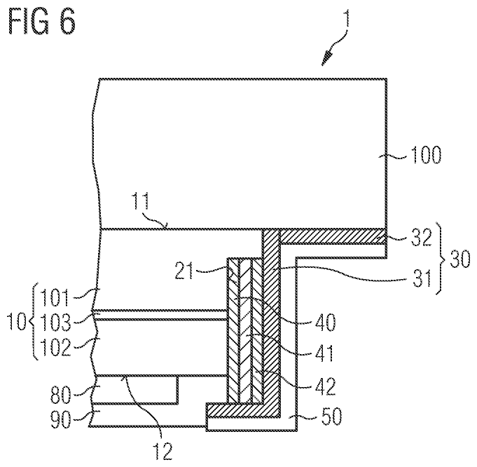

FIG. 6 shows a detail of a further exemplary embodiment of the optoelectronic semiconductor chip 1. The detail shows the semiconductor chip 1 in the region of a flank 21. FIG. 6 shows essentially the same features as FIG. 3 with the difference that a high-refractive dielectric layer 41 and a low-refractive dielectric layer 42 are arranged on the flank 21 between the second passivation layer 40 and the first passivation layer 30. The high-refractive dielectric layer 41 is disposed between the second passivation layer 40 and the low-refractive dielectric layer 42 and is in direct contact with these two layers. The high-refractive dielectric layer 41 may have a thickness which, within the scope of the production tolerance, is a quarter of the dominant wavelength.

The high-refractive dielectric layer 41 has, for example, a refractive index of at least 1.5 times as great as the refractive index of the second passivation layer 40 and the low-refractive dielectric layer 42. The high-refractive dielectric layer 41 is formed, for example, from titanium dioxide, while the low-refractive layer 42 is formed from silicon dioxide.

The invention is not limited to these by the description on the basis of the exemplary embodiments. Rather, the invention encompasses any novel feature and any combination of features, which in particular includes any combination of features in the claims, even if this feature or this combination itself is not explicitly specified in the patent claims or exemplary embodiments.

This patent application claims the priority of the German patent application DE 10 2019 122 460.8, the disclosure content of which is hereby incorporated by reference.

### LIST OF REFERENCE SIGNS

1 optoelectronic semiconductor chip
10 semiconductor body
11 top side
12 lower side
21 flank
22 bottom surface
30 first passivation layer
31 first section of the first passivation layer
32 second section of the first passivation layer
40 second passivation layer
41 high-refractive dielectric layer
42 low-refractive dielectric layer
50 metal layer
70 coupling-out structures
80 contact layer
90 insulation layer
100 growth substrate
101 first doped region
102 second doped region
103 active layer
110 mask
200 conversion layer
300 potting

1. An optoelectronic semiconductor chip comprising: a semiconductor body with an active layer, a top side and flanks running transversely to the top side;
wherein:
the active layer is configured to generate electromagnetic radiation during operation;
the flanks delimit the semiconductor body in a lateral directions;
the flanks are each covered with a first passivation layer;
a second passivation layer is arranged in each case between the first passivation layer and the semiconductor body in the region of the flanks; and
for the electromagnetic radiation generated by the active layer during operation, the refractive index of the second passivation layer is smaller than the refractive index of the first passivation layer.

2. The optoelectronic semiconductor chip according to claim 1, wherein
in each case the second passivation layer completely covers the flanks.

3. The optoelectronic semiconductor chip according to claim 1, wherein
the second passivation layer covers the flanks in each case in an amount ranging from at least 60% to at most 80%.

4. The optoelectronic semiconductor chip according to claim 1, wherein
a high-refractive dielectric layer having a greater refractive index than the second passivation layer is arranged between the first passivation layer and the second passivation layer.

5. The optoelectronic semiconductor chip according to claim 1, wherein
the second passivation layer has a thickness ranging from at least 100 nm to at most 1000 nm.

6. The optoelectronic semiconductor chip according to claim 1, wherein
a metal layer is arranged on a side of the first passivation layer facing away from the semiconductor body.

7. The optoelectronic semiconductor chip according to claim 1, wherein
the top side of the semiconductor body comprises coupling-out structures.

8. The optoelectronic semiconductor chip according to claim 6,
wherein:
the metal layer has a thickness ranging from at least 500 nm measured perpendicular to the flank;
the first passivation layer comprises two sections;
the first section runs parallel to the flank and the second section runs transversely to the flank and extends away from the semiconductor body; and
the metal layer adjoins the second section of the first passivation layer.

9. The optoelectronic semiconductor chip according to claim 1,
wherein:
the semiconductor body is based on AlₙIn₁₋ₙ₋ₘGaₘN;
the first passivation layer comprises silicon nitride; and
the second passivation layer comprises silicon dioxide.

10. A method for producing an optoelectronic semiconductor chip, wherein the method comprises:
providing a semiconductor body having an active layer, a top side and a lower side opposite the top side on a growth substrate, wherein the active layer is configured to generate electromagnetic radiation and the top side faces the growth substrate;
etching mesa trenches into the semiconductor body, starting from the lower side of the semiconductor body; wherein the semiconductor body is etched in regions of the mesa trenches to such an extent that after the etching in these regions the semiconductor body has a thickness ranging from at least 10% to at most 40% of an average thickness of the non-etched semiconductor body;
applying a second passivation layer to flanks and bottom surfaces of the mesa trenches, wherein the flanks delimit the mesa trenches in a lateral direction and the bottom surfaces delimit the mesa trenches in a vertical direction, perpendicular to the lateral direction;
removing the second passivation layer in a region of the bottom surfaces, wherein the flanks each remain covered with the second passivation layer;
applying a first passivation layer to the flanks and bottom surfaces of the mesa trenches, wherein the refractive index of the second passivation layer is smaller than the refractive index of the first passivation layer and the refractive indices respectively relate to the radiation generated by the active layer.

11. (canceled)

12. The method optoelectronic semiconductor chip according to claim 1, wherein the semiconductor body is completely absent in regions of the mesa trenches.

13. The method according to claim 10, further comprising completely removing the semiconductor body in regions of the mesa trenches.

14. The method according to claim 10, wherein the removing the second passivation layer occurs by a directed etching process.

15. The method according to claim 10, further comprising applying a high-refractive dielectric layer to the second passivation layer after the second passivation layer is applied but before the second passivation layer is removed, wherein the high-refractive dielectric layer has a higher refractive index than the second passivation layer.

16. The method according to claim 10, further comprising applying a metal layer to a side of the first passivation layer facing away from the semiconductor body.

17. The method according to claim 16, further comprising galvanically depositing a metal on the metal layer such that the mesa trenches are filled by the metal.

18. The method according to claim 10, further comprising:
removing the growth substrate; and
providing the top side of the semiconductor body with coupling-out structures.

19. An optoelectronic semiconductor chip comprising:
a semiconductor body with an active layer, a top side and flanks running transversely to the top side,
wherein:
the active layer is configured to generate electromagnetic radiation during operation;
the flanks delimit the semiconductor body in a lateral direction;
the flanks are each covered with a first passivation layer;
a second passivation layer is arranged in each case between the first passivation layer and the semiconductor body in the region of the flanks;
for the electromagnetic radiation generated by the active layer during operation, the refractive index of the second passivation layer is smaller than the refractive index of the first passivation layer; and
a lateral extent of the semiconductor body is at most 5% greater than a lateral extent of the active layer.
